(19) United States
(12) Patent Application Publication
(10) Pub. No.: US 2007/0119375 A1
(43) Pub. Date: May 31, 2007

(54) Dual large area plasma processing system

(76) Inventors: Darrin Leonhardt, Gaithersburg, MD (US); Scott G. Walton, Burke, VA (US)

Correspondence Address: NAVAL RESEARCH LABORATORY;ASSOCIATE COUNSEL (PATENTS), CODE 1008.2, 4555 OVERLOOK AVENUE, S.W., WASHINGTON, DC, 20375-5320, US

(21) Appl. No.: 11/296,708

(22) Filed: Nov. 30, 2005

(51) Int. Cl. C23C 16/00

(52) U.S. Cl. 118/723 EB

(57) ABSTRACT

A dual large area plasma processing system is provided which can comprise a substrate, a first and second electron beam wherein the substrate is positioned between the first and second electron beam, a first plasma produced by the first electron beam passing through a first gas wherein the first plasma being a first low electron temperature plasma of pre-determined width, length, thickness, and location relative to a surface; and a second plasma produced by the second electron beam passing through a second gas wherein the second plasma being a low electron temperature plasma of pre-determined width, length, thickness, and location relative to a surface. The system can include a first gas manifold that can be located above the first electron beam and control the first gas and a second gas manifold that can be located above the second electron beam and control the second gas. The system can include an external magnetic field for confining the electron beams so as to produce uniform plasmas. Also provided is a method for dual large area plasma processing which can comprise providing a first and second electron beam, providing a substrate between the first electron beam and the second electron beam, passing the first electron beam through a first gas to produce a first plasma, passing the second electron beam through a second gas to produce a second plasma, and providing a first gas manifold that can be located above the first electron beam and supply the first gas.

### BACKGROUND

The present invention pertains generally to plasma processing and more particularly to a dual large area plasma processing system (DLAPPS) wherein multiple electron beams can be used to create multiple planar plasma sources that can surround a material.

There are many processes which utilize chemical and physical surface modifications activated by plasma. These methods include etching to remove surface material, plasma-enhanced chemical vapor deposition (PECVD) to deposit new material on a surface, modifying surfaces chemically by anodizing or nitriding, physically altering by ion implantation, or heating a surface by annealing via radiation or particle bombardment. In some cases, such as semiconductor etching and some types of PECVD, it is essential that the plasma be close to the surface so that energetic ions can be drawn from the plasma toward the surface thereby activating chemical reactions. In these cases the substrate can be biased using direct current (dc) or radio frequency (rf) electric fields on the substrate or backing plate to control the ion bombardment energy. In other cases such as diamond deposition and photoresist ashing, the surface is kept out of the plasma so that it is subject to chemical action of neutral radicals generated in the plasma, but is not bombarded by ions.

For large area applications, higher ion density and lower ion bombardment energy than can be produced by capacitively coupled rf reactors are needed for some applications. Such higher density plasmas can be produced by ECR, helicon, and inductively coupled plasma sources. These plasma generators decouple the plasma production to some degree from the material's modification (“processing”) and allow one to independently control the ion bombardment energy using an rf or dc bias on the surface to be processed. These sources suffer, however, from size and uniformity limitations. The sources can also be somewhat inefficient in that they heat the entire electron population to produce and maintain the desired plasma density near the surface to be processed. They also generate large volumes of plasma outside the processing region which shed energy to the surrounding surfaces.

In all of these devices the details of the plasma distribution are influenced by the energy source, the geometry, the neutral gas density, etc. The available plasma distribution depends on a large number of parameters, all of which may have to be tuned to produce a desired plasma condition. Under many circumstances, compromises must be made between different parameters, which restricts the operating conditions available for processing.

Uniformity of feedstock gas and efficient removal of reaction products are also issues that limit the useful area and scalability in existing processing systems. Increasing processing area is extremely important to maximize throughput, and also to permit processing of large objects such as flat panel displays.

### SUMMARY OF THE INVENTION

The present invention provides for a system to independently modify multiple sides of a material to change its surface structure or composition using multiple electron beams to create planar plasma sources to surround a sheet of material. The modification to the multiple sides can occur simultaneously and the sheet of material can be suspended. The present invention provides for a decreased processing time and improved process reproducibility. The electron beam produced plasmas can be capable of delivering substantial ion and radical fluxes at low temperatures over large areas.

The present invention relates to a means to form two large area high electron density uniform plasmas whose length and width can be 10's-100's of cm and very much larger than the plasma thickness of approximately 1 cm. The present invention provides for a system where the plasma distribution can be created independent of both the surface to be processed and the (dc or rf) bias voltage applied between the plasma and the surface. Furthermore, the present invention provides for a system for generating a beam-produced plasma at a lower electron temperature (Tₑ) and one in which Tₑ can be controlled by the user.

A dual large area plasma processing system (DLAPPS) can provide for a device wherein the free radical formation can be controlled externally by adjusting Tₑ, the pulse duration, beam energy, etc. A dual large area plasma processing system can be a system where it can be possible to place each side of a substrate in close proximity to a plasma, and to control the bombardment of the substrate by energetic ions, or if desired, to prevent any substantial bombardment by energetic ions.

A dual large area plasma processing system can provide a plasma geometry which permits independent uniform gas feed and more uniform removal of reaction products at each surface. The DLAPPS geometry can also have a large available area directly in front of the substrate for pumping process products out of the processing chamber and cathode chamber so as not to contaminate the material being processed or damage the cathode.

With DLAPPS, multiple electron beams can be used to create multiple large area sheets of plasma that are independent of the surface to be processed, the bias applied to the surface and the reactive gases being delivered. The beam produced plasmas also have advantages in plasma production efficiency, plasma electron temperature, ion flux control, and free radical production. The beam ionization technique can be an efficient means to ionize a cold neutral gas, ionizing only the region exposed to the beam. The resultant plasmas have a very low electron temperature. This intrinsically low electron temperature can, if desired, be increased in a controlled way by plasma heating, allowing additional control of the ion energy independent of the bias voltage.

Beam production of free radicals is also much more efficient than production via bulk plasma heating. Combined with electron temperature control it is possible to also adjust the free radical species or density.

Independently heating or cooling the stage can also control the temperature of the stage and the material to be processed.

### BRIEF DESCRIPTION OF THE DRAWINGS

FIG. 1 shows a dual large area plasma processing system.

### DESCRIPTION

The present invention provides for an improved approach for altering the chemical and physical features of a material using electron beam generated plasmas. Using a multiple cathode system is more efficient than a single cathode system. Processing times can be reduced in half by processing both sides simultaneously. The uniformity of the process can be increased because DLAPPS surrounds the substrate with plasma.

In contrast, systems that process one substrate side at a time suffer from chemical “loading” of the substrate due to poor gas flow utilization and systems that suspend the substrate but use one plasma source suffer from relying on the gas phase diffusion of plasma species for process uniformity on both sides of the substrate.

The present invention provides for a means to simultaneously modify both sides of a material to change its surface structure or composition. Applications include but are not limited to treatment of organic and textile materials to change wetting characteristics, surface morphology and general appearance. These applications can also be precursor steps for the adhesion of metallic and non-metallic coatings. The present invention provides for a means to independently alter the chemical and physical nature of both sides of a material surface.

The present invention provides for a means to form large area high electron density uniform plasmas whose length and width can be as large as 10's-100's of cm and very much larger than the plasma thickness (≈1 cm).

The present invention provides for a system where the plasma distribution can be created independent of both the surface to be processed and the bias voltage (direct current or radio frequency) applied between the plasma and the surface.

The present invention provides for a system for producing beam-produced plasmas at a lower electron temperature (Tₑ) and in which Tₑ can be controlled.

The present invention can produce a device wherein the free radical formation can be controlled externally by adjusting Tₑ, the pulse duration, beam energy, etc.

The present invention can be a system where it is possible to place a substrate in close proximity to a plasma, and to control the bombardment of the substrate by energetic ions, or if desired, to prevent any substantial bombardment by energetic ions.

The present invention can produce plasmas for plasma processing applications in a plasma geometry which permits independent uniform gas feed and more uniform removal of reaction products for each surface being modified.

The present invention, a dual large area plasma processing system (DLAPPS) concerns a system wherein multiple electron beams can be used to create dual large area uniform sheets of plasma that are independent of the surface to be processed and the bias applied to the surface. The beam produced plasmas also have advantages in plasma production efficiency, plasma electron temperature, ion flux control, and free radical production.

This beam ionization technique is an efficient means to ionize a cold neutral gas, ionizing only the region exposed to the beam. The resultant plasmas have a very low electron temperature. This intrinsically low electron temperature can, if desired, be increased in a controlled way by plasma heating, allowing the control of the ion flux through the ion sound speed independent of the bias voltage. Beam production of free radicals is also much more efficient than production via bulk plasma heating. Combined with electron temperature control, it can be possible to adjust the free radical species or density.

In addition, a material being processed can be placed in close proximity to the plasma without substantial bombardment by energetic ions, if desired. The DLAPPS geometry also has a large available area for pumping process byproducts out of the processing chamber and cathode chamber so as not to contaminate the material being processed or damage the cathode. The temperature of the stage and the material to be processed can also be controlled by independently heating or cooling the stage.

The present invention enhances a LAPPS that is described in U.S. Pat. No. 5,874,807, the entire contents of which are herein incorporated by reference. This LAPPS utilized an electron beam produced plasma capable of delivering substantial ion and radical fluxes at low temperatures over large areas. Electron beam produced plasmas allow greater control over the relative radical and ion fluxes, thereby permitting a large process space and the ability to treat a wide variety of substrates.

The present invention utilizes multiple electron beams to create an additional planar plasma source to surround a suspended sheet of material. The reactive plasma species will completely surround the material, thereby decreasing the processing time and improving the process reproducibility. The system can be configured with additional sputter sources or used for the double-sided metallization of substrates. The present invention can implement multiple electron beam generated plasma sources for simultaneously treating both surfaces of the same substrate.

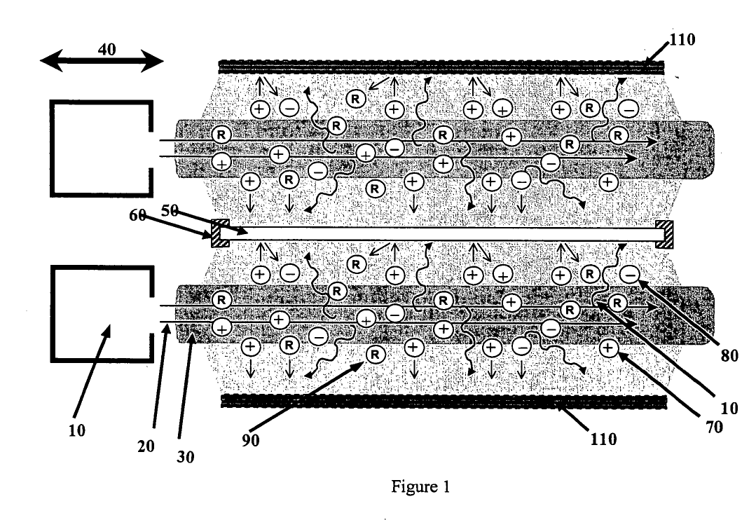

The dual large area plasma processing system (DLAPPS) shown in FIG. 1 is a way of forming dual large area sheet plasmas 30. The multiple adjustable parameters available to the system can enable a wide range of tuning capability, as well as optimization for diverse applications. It can offer a means of making large, uniform plasma distribution in a wide variety of gases. The control of the pulse length and rapid turn on and off times can provide the means to create a large range of conditions for different plasma processing operations.

In one embodiment, the device uses a magnetically confined sheet electron beam to ionize a background gas and produce a planar plasma. Electron beams can exhibit high ionization and dissociation efficiency with the ionization process (‘plasma production’) decoupled from the gas constituents and reactor geometry. Since usually only the beam dimensions limit the plasma volume, the usable surface area of these plasmas can significantly exceed that of the other plasma sources. Rectangular plasmas with a thickness of about 1 cm and an active area of about 1 m² have been produced.

The present invention can produce plasmas that can possess the desired characteristics for a surface modification tool. The process gas mixture and plasma-to-substrate separation can tightly control radical and ion flux, while process uniformity can be maintained over large surface areas. Ion energies are inherently low (<5 eV) and thus tend to favor predominantly chemical surface processes, while processes requiring higher energies (i.e. etching) can be achieved by applying an external bias to the substrate. This inherent control over the ion energies (from one to hundreds of electron-volts) is not present in any other plasma pretreatment systems. In fact, for most systems the inability to prevent high energies often leads to undesirable heating and ion damage of delicate substrates.

Furthermore, due to the beam-ionization mechanism, fewer excited states exist in the plasma species, which reduces UV emission from the source. Therefore, a process where polymer cross-linking is undesirable (i.e. metallization) will be better optimized; for a process requiring UV activation, longer process times can be used without additional ion damage since the ion energies are inherently low. This combination of features and the ability to scale to large areas adds a range of control variables that would enable the system to access operating regimes not possible with conventional plasma treatment technologies.

The present invention extends the scope of materials processing with electron beam generated plasmas by incorporating an additional electron beam to allow double-sided processing of substrates. Other attempts have been made at “double-sided” processing but these attempts referred to processing two substrates using both sides of one plasma sheet. The present invention utilizes an additional plasma source to process both sides of a single substrate simultaneously.

In another embodiment, DLAPPS can be based on magnetically confined sheet electron beams to ionize and dissociate a background gas. The electron beam energy is nominally a few kiloelectron-volts (keV) or less with beam current density ranging from 0.1 to 10 mA/cm2. The beam width can be variable and can exceed a meter. The thickness can be up to a few centimeters and is maintained over the beam length by an axial magnetic field that exceeds 100 Gauss. In this embodiment, the same magnetic field can be used for both electron beams. The length of each plasma sheet can be determined by the range of the electron beam, and scales with the beam energy and gas pressure. The range is usually maintained at several times the system length to ensure uniformity in plasma production. The gas pressure typically lies between 10 and 100 mTorr. For the parameters, the beam range can be greater than 1 m and the plasma densities can be as high as about 10¹² cm⁻³. DLAPPS can be capable of treating both sides of substrates exceeding 1 m². DLAPPS greatly extends the versatility of electron beam generated plasmas and allows for a fundamentally different approach for applications in materials processing.

The present invention can be operated in multiple configurations. In another embodiment, a substrate would be suspended between the two electron beams with a rigid bridge-like support stage. The support stage can be externally biasable, if desired. In another embodiment, additional stages can be added on the outer faces of the electron beams, as shown in FIG. 1. The biasing capabilities are not shown in FIG. 1. The various processing applications that can be carried out include but are not limited to plasma enhanced chemical vapor deposition, plasma enhanced physical vapor deposition, and surface activation.

In one example, a two-beam system similar to that shown in FIG. 1 was constructed. Two hollow cathodes were used to generate the high energy electron beams, mounted 5 cm apart (center-to-center). The cathodes for this example were only 12 cm in length, but scaling up these sources has been demonstrated successfully. The prototype system was tested with a 35:10 ration of argon and oxygen (by flow) and a pressure of 73 mtorr. The cathodes were driven by the same −2 kV, 2 ms pulses at 50 Hz and the magnetic field strength was 180 Gauss. This example was chosen for convenience and can be optimized for any processing application.

Additional flexibility can be achieved by operating the cathodes with separate power supplies. In this embodiment the cathodes can be independently addressable (different voltages, pulse widths) allowing further processing refinement. The cathodes can also be of different designs (i.e. lengths, widths, or non-linear), different orientations (nonparallel or counter-propagating electron beams), greater than two in number, or run continuously.

Further flexibility can be achieved by independently addressing the gas feeds (gas introduction and removal) to each surface. These gas feeds can be located directly opposite the substrate on the other side of the electron beam. The gas feeds can also be proportional to the surface being processed, which can also increase process uniformity.

In another embodiment and usually for the treatment of substantial quantities of flexible substrates, a roll-to-roll system can be implemented to feed long lengths of material through the system thereby doubling the plasma exposure on both sides of the substrate. The use of all sides of the two sources can be similar to the placement of the auxiliary stages 110 shown in FIG. 1. However, instead of the multiple substrates, the substrate can now be all one piece which serpentines between and around the electron beams.

The DLAPPS 10 can be designed to produce beams 20 and sheet plasmas 30 over an area between several hundred square centimeters to several square meters. The plasmas 30 can be made spatially uniform over the lateral dimensions or can be given a lateral profile chosen for a particular application. The thickness of the sheet plasmas 30 can be controlled by the cathode 10 size and magnetic field parameters. The plasmas 30 thickness can be as small as 1 cm, although it may be desirable for some applications to produce a lower density, wider plasma distribution. Across its thickness, the plasma density can be peaked, with a maximum density as large as 5×10¹² cm⁻³. Lower densities can be possible by adjusting the beam 12 and gas density parameters.

The electron beams 20 generating the plasmas 30 can be produced by a linear cathode beam source driven by a beam voltage generator 10 located in a cathode chamber adjacent to a processing chamber. The beam density necessary to produce this plasma density can be about 50 mA/cm² or less. A linear cathode 10 is the preferred type of beam source, although other types of sources such as hot filaments, field emission sources, or radio frequency (rf) plasmas, can be useful for particular applications. The beam voltage generator 10 can be pulsed or continuous for different processing applications. The beam source 10 can be segmented to allow spatial control of the beam 20 current and energy in the lateral dimension. Feedback tuning of the beam 20, plasmas 30, or process rate can be introduced through the cathode 10.

The beam 20 energy can be selected so that the beam 20 electrons can propagate to the end of the processing region without losing their full energy. Typically this can require an electron energy of 1-5 keV, depending on the gas pressure and species in the processing chamber. The composition and pressure of the gas being supplied through openings 46 and the rate of gas feed, can be chosen to meet the needs of each type of process. The beam 20 can exit the chamber through a second rectangular aperture isolating a beam dump chamber. After passing through the exit aperture, the beam 20 can be absorbed by a beam dump. Debris from the beam dump, if any, can be confined to the beam dump chamber. A reverse-biased system can be used to recover the beam 20 energy within the beam dump chamber.

A steady state magnetic field of approximately 100 to 200 Gauss can be imposed along the direction of the beam 20 propagation by a series of rectangular or other shaped electromagnets, with appropriate cooling (not shown) to permit continuous operation. A very uniform field can be generated with coils that are widely spaced, permitting the area between coils to be used for gas inflow and pumping. This field can confine the beam 20 electrons to a narrow sheet 30 as they propagate through the processing chamber. The field can be controlled by adjusting the current in each coil to focus or defocus the beam or change its location depending on the desired plasma conditions and processing geometry.

The thickness of the sheets 30 can be comparable to or larger than the transverse Larmor diameter of the beam 20 electrons in the magnetic field and can be determined in part by the scattering of the beam 20 electrons by the gas. This can serve as a condition for choosing the strength of the field. In typical applications where the sheets 30 thickness is 1 cm, the field strength can be about 150 Gauss. Also, it can be desirable to have a continuous flow process, wherein the coils can be configured so as to leave an opening on the sides of the chamber to allow for the substrate or material 50 to be moved through the chamber without having to cycle the vacuum system.

The beam 20 can enter the processing chamber via a narrow slit which can serve three purposes: first, the slit can isolate the processing plasma 30 electrically from the diode voltage. Second, the slit can clearly define the edge of the beam 20, and therefore the edge of the plasma 30. Third, the slit can permit differential pumping through ports to maintain a pressure difference between the source region in the outer chamber and the processing chamber. The slit can also be altered mechanically or the beam 20 location relative to the slit changed using an auxiliary magnetic field in order to tune or alter the beam 20 (and therefore plasma 30) conditions in the processing chamber.

The substrate or sample 50 to be processed can be mounted on a planar stage 60 which can be oriented parallel (or in some cases at a slight angle) to the plasma sheets 30. The separation between the plasmas 30 and the stage 60 can be adjusted by moving the stage 60, and/or magnetically adjusting the location of the plasmas 30. Typically, the stage 60 can be shielded from direct impact by the electron beam 20 by the entrance slit 18. The substrate 50 can be located adjacent to the edge of the plasma 30 or it can be separated from the edge by a distance chosen to be up to several cm away. The ion bombardment energy can be determined separately using an rf bias (not shown) or a dc voltage on the stage 60. The stage 60 can also represent a surface that can be scrolled perpendicular to the beam 30 direction for continuous feed surface treatment processing.

Also shown in FIG. 1 is an example of a possible distribution of positive ions 70 and electrons and/or negative ions 80 and neutral radicals 90 and UV photons 100.

Experimentation has shown that a DLAPPS plasmas 30, again referring to FIG. 1, can be produced which can be uniform in peak plasma 30 density to better than 10% over the present 0.6 meters in length and much better than 10% over its 0.6 meter width. The non-uniformity can consist primarily of a systematic spreading of the plasma sheet, and decrease in the plasma density, over the length, due to scattering off the background gas. The plasma species densities, integrated over the thickness of the plasma sheet, can be uniform to a much greater extent. Scaling up to several square meters is possible. Plasma uniformity can be improved changing the cathode 10 voltage or lateral current density profile or by slightly increasing the magnetic field strength as a function of distance from the source 10 to compensate for beam 20 spreading. In addition, uniformity of the process can be improved by compensation techniques, e.g., tilting the processing stage 60 with respect to the plane of the plasma 30; using multiple, independently controlled beam sources 10 to improve the uniformity of the plasma 30; moving the beam 20 laterally by changing the magnetic field; or rotating the stage 60 to average out the plasma 30. Processes that depend on integrated charge or free radical production rather than peak density may not require the use of these techniques due to the planar geometry.

The DLAPPS 10 technique essentially decouples plasma production from the processing geometry. The plasma 30 can be produced by the electron beam 20 which can be set by the cathode 10 and magnetic field geometry. Thus the plasma 30 distribution can be moved independent of the surface to be processed and the bias (not shown) applied to the surface. This allows large area plasmas 30 to be formed, limited only by the ability to produce a uniform electron beam 20. The two-dimensional character of the plasma 30 also improves the plasma 30 uniformity, eliminating edge effects and electromagnetic mode dependent plasma density variations. It also allows maximum access to the plasma 30 and surfaces to be processed for real-time sensors and the ability to control the plasma 30 through the beam 20 and magnetic fields to maintain a desired level of uniformity. The planar geometry also allows more uniform gas feed and byproduct or debris removal, resulting in more uniform processing. Independent showerhead-like gas flow feeds can be positioned directly above each surface.

The DLAPPS 10 plasma also has significant advantages over existing processing plasmas. A beam-produced plasma has a much lower plasma electron temperature than industry standard capacitive or inductively coupled plasmas. As a result, many of the excited states of the atoms or molecules are characterized by a lower density and temperature. The low intrinsic plasma electron temperature also allows for independent control of the temperature, if desired. An rf discharge current can be passed through the plasma distribution allowing one to heat the plasma electrons to a desired temperature. The low plasma electron temperature occurs because the beam energy ends up primarily in direct ionization and free radical formation, rather than in low-lying excitations and heating of the bulk plasma electrons (beam electrons both produce free radicals directly as well as via dissociative recombination of the background gas, making it an efficient process). Typical plasma electron energies will be less than 1 eV in a DLAPPS 10 plasma 30. In many processes the production of free radicals is essential, either by themselves or as part of an ion impact process. By using pulsed rather than continuous beams and allowing the plasma 30 to relax between pulses, there can be further control of the radical formation. This can result in plasma chemistry that can be varied by the choice of beam pulse length, pulse separation, and by controlling the plasma electron temperature.

The geometry and low temperature of the DLAPPS 10 plasma 30 facilitates control over extraction of ions from the plasma. In most parameter regimes of interest, the cross-[magnetic]field mobility of the ions will exceed that of the plasma electrons. The lower electron temperature will then decrease the ion flow leaving the plasma, causing the floating potential to be small or positive. Ion bombardment characteristics can be controlled by the bias (not shown) applied to the stage 60. It can be possible to operate with highly directional ion bombardment at the chosen energy, e.g., for anisotropic etching. On the other hand, it can be possible to operate with the substrate 60 just outside the plasma 30 so that a copious flux of neutral radicals can be delivered to the substrate 60, for applications such as diamond deposition, while allowing only minimal low energy ion flux on the substrate 60.

The DLAPPS 10 source offers significant advantages and new capabilities in the physical size and geometry of the device as well as in the increased control of the plasma 30 produced. The geometric advantages of the DLAPPS 10 primarily impact process productivity as well as allowing processing of larger area surfaces. The improved control of the plasma 30 provides better control of existing processing techniques as well as offering new capabilities for advanced techniques.

The DLAPPS 10 production of the plasma is divorced from all other aspects of the plasma processing. In DLAPPS 10, the geometry of the plasma can be set with an external source. The DLAPPS 10 utilizes an electron beam 20 injected into a neutral gas where ionization occurs, thus providing a means of forming a large area uniform plasma whose length and width can comparable (10's-100's of cm) and larger than the plasma thickness (about 1 cm). The plasma distribution can be created independent of the surface to be processed and the bias applied to the surface. The beam-produced plasma 30 has a lower electron temperature than the prior art systems, and the formation of radicals can be better controlled. The substrate 60 can be placed in close proximity to the plasma 30 without substantial bombardment by energetic ions. The gas injection and removal may be independently tailored for each surface during the same treatment.

Although the invention has been described in relation to an exemplary embodiment thereof, it is understood by those skilled in the art that still other variations and modifications can be affected in these preferred embodiments without detracting from the scope and spirit of the invention as described in the claims.

What is claimed is:

1. A dual large area plasma processing system, comprising:
a substrate;
a first electron beam;
a second electron beam wherein said substrate is positioned between said first electron beam and said second electron beam;
a first plasma produced by said first electron beam passing through a first gas wherein said first plasma being a first low electron temperature plasma of pre-determined width, length, thickness, and location relative to a surface; and
a second plasma produced by said second electron beam passing through a second gas wherein said second plasma being a low electron temperature plasma of pre-determined width, length, thickness, and location relative to a surface.

2. The system of claim 1, further including a first gas manifold that can be located above said first electron beam and control said first gas.

3. The system of claim 2, further including a second gas manifold that can be located above said second electron beam and control said second gas.

4. The system of claim 1, further including an external magnetic field for confining said first electron beam and said second electron beam so as to produce a first spatially uniform plasma and a second spatially uniform plasma.

5. The system of claim 1, further including a target comprising a material source for thin films or coatings wherein said first plasma and said second plasma deposit said material upon said substrate.

6. The system of claim 1, further including a means for predetermining and adjusting the plasma across the dimension transverse to the first electron beam flow and second electron beam flow and along the first electron and the second electron beam propagation and direction to suit a predetermined application.

7. The system of claim 6, wherein the means for predetermining and adjusting the plasma is by controlling a cathode emission profile.

8. The system of claim 6, wherein the means for predetermining and adjusting the plasma is by the use of different beam limiters.

9. The system of claim 6, wherein the means for predetermining and adjusting the plasma is by controlling a magnetic field geometry.

10. The system of claim 1, further including a means for independently increasing an initial plasma electron temperature to a predetermined level.

11. The system of claim 10, wherein the means for independently increasing the initial plasma electron temperature to a predetermined level is by passing a direct current through the plasma.

12. The system of claim 10, wherein the means for independently increasing the initial plasma electron temperature to a predetermined level is by passing radio frequency current through the plasma.

13. The system of 10, wherein the means for independently increasing the initial plasma electron temperature to a predetermined level is by heating the plasma with an external microwave source.

14. The system of claim 1, further including a means for pulsing a plasma density.

15. The system of claim 14, wherein the means for pulsing the plasma density is by pulsing the electron beam.

16. The system of claim 1, further including a means for biasing a surface at a predetermined voltage with respect to the plasma.

17. The system of claim 16, wherein the means for biasing the surface at a predetermined voltage with respect to the plasma is by using a constant voltage to control extraction of ions from the plasma.

18. The system of claim 16, wherein the means for biasing the surface at a predetermined voltage with respect to the plasma is by using a radio frequency voltage to control an extraction of ions from the plasma.

19. The system of claim 1, further including a means for heating/cooling a surface.

20. The system of claim 1, further including a means for producing free radicals from a background gas.

21. The system of claim 20, wherein the means for producing free radicals from the background gas is by electron bombardment processes.

22. The system of claim 1, further including a means for producing concentrations of free radicals in the plasma.

23. The system of claim 1, further including a means for controlling free radical production.

24. The system of claim 23, wherein the means for controlling free radical production is by pulsing the beam.

25. The system of claim 1, further including a means for introducing a gas above said substrate without obstructing the trajectory of said electron beam wherein said gas includes the constituents selected to suit a predetermined application.

26. The system of claim 25, further including a means for removing said gas above said substrate without obstructing the trajectory of said electron beam.

27. A dual large area plasma processing system, comprising:
a first and a second electron beam wherein a substrate is positioned between said first and said second electron beam;
a means for producing a first low electron temperature plasma of a first predetermined width, length, thickness, and location relative to a surface;
a means for producing a second low electron temperature plasma of a second predetermined width, length, thickness, and location relative to a surface;
a means for introducing a gas above said substrate without obstructing the trajectory of said electron beams wherein said gas includes the constituents selected to suit a predetermined application;
a means for removing said gas above said substrate without obstructing the trajectory of said electron beams; and
a means for magnetizing the beam so as to produce a geometrically well defined, spatially uniform thin plasma.

28. A method for dual large area plasma processing, comprising:
providing a first electron beam and a second electron beam;
providing a substrate between said first electron beam and said second electron beam;
passing said first electron beam through a first gas to produce a first plasma;
passing said second electron beam through a second gas to produce a second plasma; and
providing a first gas manifold that can be located above said first electron beam and supply said first gas.
